(19) United States
(12) Patent Application Publication
(10) Pub. No.: US 2024/0101472 A1
(43) Pub. Date: Mar. 28, 2024

(54) METHOD OF MANUFACTURING WINDOW, WINDOW MANUFACTURED THEREBY, AND DISPLAY DEVICE INCLUDING THE WINDOW

(71) Applicant: Samsung Display Co., Ltd., Yongin-si (KR)

(72) Inventors: WON-JONG BAEK, Yongin-si (KR); TAEHO AN, Yongin-si (KR)

(73) Assignee: Samsung Display Co., Ltd., Yongin-si (KR)

(21) Appl. No.: 18/354,757

(22) Filed: Jul. 19, 2023

(30) Foreign Application Priority Data
Sep. 27, 2022 (KR) 10-2022-0122069

(51) Int. Cl. C03C 21/00; H05K 5/03

(52) U.S. Cl. CPC C03C 21/005; C03C 21/002; H05K 5/03

(57) ABSTRACT

Provided is a method of manufacturing a window, which includes preparing a first preliminary glass substrate including Li⁺ ions and Na⁺ ions, providing a first strengthening molten salt including Na⁺ ions onto the first preliminary glass substrate and forming a second preliminary glass substrate, providing a second strengthening molten salt including Rb⁺ ions onto the second preliminary glass substrate and forming a third preliminary glass substrate, and providing a third strengthening molten salt including K⁺ ions onto the third preliminary glass substrate and forming a strengthened glass substrate.

### CROSS-REFERENCE TO RELATED APPLICATIONS

This application claims priority to and benefits of Korean Patent Application No. 10-2022-0122069 under 35 U.S.C. § 119, filed on Sep. 27, 2022 in the Korean Intellectual Property Office, the entire contents of which are incorporated herein by reference.

### BACKGROUND

### 1. Technical Field

The disclosure herein relates to a method of manufacturing a window, which may include ion exchange strengthening performed multiple times, a window manufactured thereby, and a display device including the window.

### 2. Description of the Related Art

Display devices are activated in response to electrical signals, and include a window, a housing, and an electronic element. The electronic element may include various types of elements activated in response to electrical signals, such as a display element, a touch element, or a detection element.

The window is disposed on a front side of a display device to protect the electronic element and provide active regions to users. The electronic element may be stably protected from external shocks through the window. Accordingly, a method of strengthening a window to exhibit excellent strength is being studied.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a window exhibiting improved strength and a method of manufacturing the window.

The disclosure also provides a display device including a window exhibiting improved strength.

An embodiment may include a method of manufacturing a window, which may include preparing a first preliminary glass substrate including Li⁺ ions and Na⁺ ions; providing a first strengthening molten salt including Na⁺ ions onto the first preliminary glass substrate and forming a second preliminary glass substrate; providing a second strengthening molten salt including Rb⁺ ions onto the second preliminary glass substrate and forming a third preliminary glass substrate; and providing a third strengthening molten salt including K⁺ ions onto the third preliminary glass substrate and forming a strengthened glass substrate.

In an embodiment, the first strengthening molten salt may include NaNO₃.

In an embodiment, the second strengthening molten salt may include Na⁺ ions.

In an embodiment, the Na⁺ ions may be present at a proportion in a range of about 60% to about 90%, and the Rb⁺ ions may be present at a proportion in a range of about 10% to about 40% with respect to a total cation concentration of the second strengthening molten salt.

In an embodiment, the third strengthening molten salt may include Rb⁺ ions.

In an embodiment, the K⁺ ions may be present at a proportion in a range of about 60% to about 90%, and the Rb⁺ ions may be present at a proportion in a range of about 10% to about 40% with respect to a total cation concentration of the second strengthening molten salt.

In an embodiment, the first strengthening molten salt may be provided at a temperature in a range of about 380° C. to about 420° C. for a period in a range of about 30 minutes to about 3 hours in the forming of the second preliminary glass substrate.

In an embodiment, the second strengthening molten salt may be provided at a temperature in a range of about 380° C. to about 420° C. for a period in a range of about 30 minutes to about 3 hours in the forming of the third preliminary glass substrate.

In an embodiment, the third strengthening molten salt may be provided at a temperature in a range of about 380° C. to about 450° C. for a period in a range of about 10 minutes to about 2 hours in the forming of the strengthened glass substrate.

In an embodiment, the strengthened glass substrate may include a compressive stress layer having a compressive stress of about 1400 MPa or less as measured through a method of ASTM C770-16, and the compressive stress layer may have a thickness in a range of about 90 μm to about 130 μm.

In an embodiment, the method of manufacturing a window according to an embodiment may further include forming a printing layer overlapping a portion of the strengthened glass substrate in plan view after the forming of the strengthened glass substrate.

In an embodiment, a window may include a strengthened glass substrate including Na⁺ ions, K⁺ ions, and Rb⁺ ions. The strengthened glass substrate may include a base layer having a compressive stress value of zero, and a compressive stress layer disposed on at least one of an upper surface or a lower surface of the base layer. The compressive stress layer may include a first region having a first compressive stress change rate, a second region having a second compressive stress change rate less than the first compressive stress change rate, and a third region having a third compressive stress change rate less than the second compressive stress change rate. Each of the first compressive stress change rate, the second compressive stress change rate and the third compressive stress change rate are a compressive stress change rate according to depth with respect to a thickness direction. A minimum depth from a surface of the strengthened glass substrate to a border between the first region and the second region is in a range of about 5 μm to about 15 m, with respect to the thickness direction, a minimum depth from a surface of the strengthened glass substrate to a border between the second region and the third region is in a range of about 20 μm to about m, and the compressive stress layer has a thickness in a range of about 100 μm to about 130 μm.

In an embodiment, the first region may be spaced apart from the base layer with the second region and the third region disposed between the first region and the base layer.

In an embodiment, the compressive stress layer may have a thickness in a range of about 13% to about 25% with respect to 100% of a total thickness of the strengthened glass substrate.

In an embodiment, the strengthened glass substrate may have a thickness in a range of about 500 μm to about 700 μm.

In an embodiment, an upper surface of the first region may define a surface of the strengthened glass substrate. A maximum value of compressive stress measured through a method of ASTM C770-16 in the surface may be in a range of about 1000 MPa to about 1400 MPa.

In an embodiment, compressive stress through a method of ASTM C770-16 at the border between the second region and the third region may be about 140 MPa or greater.

In an embodiment, compressive stress measured through a method of ASTM C770-16 at a depth of about 30 μm from the surface of the strengthened glass substrate may be about 140 MPa or greater with respect to the thickness direction.

In an embodiment, compressive stress measured through a method of ASTM C770-16 at a depth of about 50 μm from the surface of the strengthened glass substrate may be about 80 MPa or greater with respect to the thickness direction.

In an embodiment, a display device may include a display module; and a window disposed on the display module and including a compressive stress layer. The compressive stress layer may include a first region having a first compressive stress change rate; a second region having a second compressive stress change rate different from the first compressive stress change rate; and a third region having a third compressive stress change rate different from the first compressive stress change rate and the second compressive stress change rate, and each of the first compressive stress change rate, the second compressive stress change rate, and the third compressive stress change rate is a compressive stress change rate according to depth with respect to a thickness direction. A minimum depth from a surface of the window to a border between the first region and the second region is in a range of about 5 μm to about 15 m, with respect to the thickness direction, a minimum depth from a surface of the window to a border between the second region and the third region with respect to the thickness direction is in a range of about 20 μm to about 40 m, and the compressive stress layer has a thickness in a range of about 100 μm to about 130 μm.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1 is a schematic perspective view showing a display device of an embodiment;

FIG. 2 is an exploded perspective view of a display device according to an embodiment;

FIG. 3 is a schematic cross-sectional view showing a window according to an embodiment;

FIG. 4 is a schematic cross-sectional view showing components of a window according to an embodiment;

FIG. 5 is a graph schematically showing compressive stress according to depth of a compressive stress layer according to an embodiment;

FIG. 6 is a flowchart showing a method of manufacturing a display device of an embodiment;

FIGS. 7A to 7D schematically show stages in a method of manufacturing a window of an embodiment;

FIG. 8 schematically shows a window manufacturing device that performs stages of a method of manufacturing a window in a process of a method of manufacturing a window of an embodiment; and

FIG. 9 is a graph showing compressive stress according to depth in windows of Comparative Examples and Examples.

### DETAILED DESCRIPTION OF THE EMBODIMENTS

The disclosure may be modified in many alternate forms, and thus embodiments will be illustrated in the drawings and described in detail. It should be understood, however, that it is not intended to limit the disclosure to the forms disclosed, but rather, is intended to cover all modifications, equivalents, and alternatives falling within the spirit and scope of the disclosure.

In the drawings, sizes, thicknesses, ratios, and dimensions of the elements may be exaggerated for ease of description and for clarity. Like numbers refer to like elements throughout.

As used herein, when an element (or a region, a layer, a portion, etc.) is referred to as being “on,” “connected to,” or “coupled to” another element, it means that the element may be directly connected to/coupled to the other element, or that a third element or other elements may be disposed therebetween.

It will be understood that the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure.

As used herein, the singular forms, “a,” “an,” and “the” are intended to include the plural forms as well, unless the context clearly indicates otherwise.

Terms such as “below,” “lower,” “above,” “upper,” and the like are used to describe the relationship of the configurations shown in the drawings. The terms are used as a relative concept and are described with reference to the direction indicated in the drawings.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It should be understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

As used herein, being “disposed directly on” may mean that there is no additional layer, film, region, plate, or the like between a part and another part such as a layer, a film, a region, a plate, or the like within the spirit and the scope of the disclosure. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a window according to an embodiment and a display device including the same will be described with reference to the accompanying drawings.

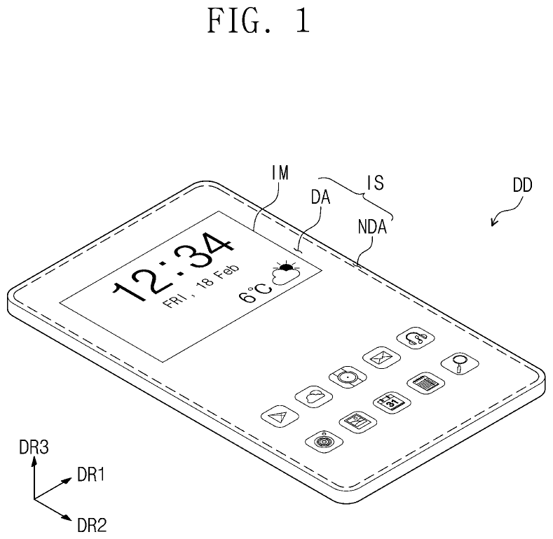

FIG. 1 is a schematic perspective view showing a display device according to an embodiment.

A display device DD may be a device activated according to electrical signals. The display device DD may be a flexible device. For example, the display device DD may be a portable electronic device, a tablet, a car navigation system, a game console, a personal computer, a laptop computer, or a wearable device, but is not limited thereto. In FIG. 1, a portable electronic device is presented as an example of the display device DD.

The display device DD may display an image IM through a display surface IS. The display surface IS may include a display region DA and a non-display region NDA adjacent to the display region DA. The non-display region NDA may be a portion in which images are not displayed. However, an embodiment is not limited thereto, and the non-display region NDA may be omitted. The display surface IS may include a plane defined by a first direction DR1 and a second direction DR2.

The first direction DR1 and the second direction DR2 herein may be perpendicular to each other, and a third direction DR3 may be a normal direction to a plane defined by the first direction DR1 and the second direction DR2. A thickness direction of the display device DD may be parallel to the third direction DR3. An upper surface (or a front surface) and a lower surface (or a rear surface) of members constituting the display device DD herein may be defined with respect to the third direction DR3. Directions indicated by the first to third directions DR1, DR2, and DR3 as described herein are relative concepts, and may thus be changed to other directions.

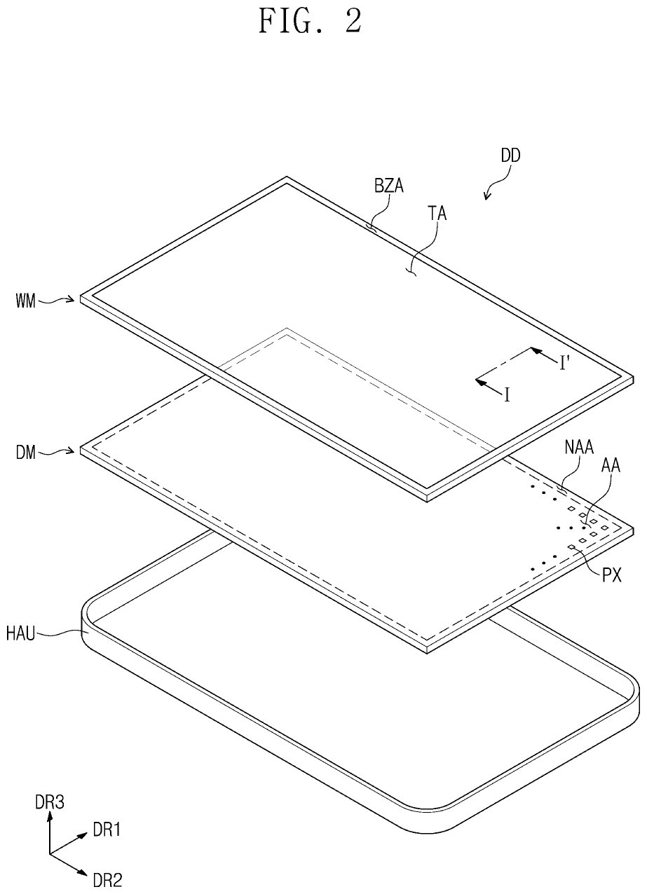

FIG. 2 is an exploded perspective view of a display device according to an embodiment. The display device DD may include a display module DM and a window WM disposed on at least one of an upper portion or a lower portion of the display module DM. In FIG. 2, the window WM is shown to be disposed above the display module DM, but this is presented as an example, and the window WM may be disposed both above and below the display module DM.

The display device DD may further include a housing HAU accommodating the display module DM. In the display device DD shown in FIGS. 1 and 2, the window CW and the housing HAU may be combined together to form an exterior of the display device DD. The housing HAU may be disposed below the display module DM. The housing HAU may include a material having a relatively higher rigidity. For example, the housing HAU may include frames and/or plates formed of glass, plastic, or metal. The housing HAU may provide a selectable place for accommodation. The display module DM may be accommodated in the accommodation place to be protected from external shocks.

The display module DM may be activated according to electrical signals. The display module DM may be activated to display the image IM on the display surface IS of the display device DD. The display module DM may be activated to detect external inputs applied to an upper surface. The external inputs may include a user's touch, contact or proximity of intangible objects, pressure, light, or heat, and are not limited to any one embodiment.

The display module DM may include an active region AA and a peripheral region NAA. The active region AA may be a portion providing the image IM (FIG. 1). In the active region AA, a pixel PX may be disposed. The peripheral region NAA may be adjacent to the active region AA. The peripheral region NAA may cover the active region AA. A driving circuit, a driving line, or the like for driving the active region AA may be disposed in the peripheral region NAA.

The display module DM may include pixels PX. Each of the pixels PX may display light in response to electrical signals. The light displayed by the pixels PX may implement the image IM. Each of the pixels PX may include a display element. For example, the display element may be an organic light emitting element, a quantum dot light emitting element, an electrophoretic element, an electrowetting element, or the like within the spirit and the scope of the disclosure.

The window WM may include a transmission region TA and a bezel region BZA. The transmission region TA may overlap at least a portion of the active region AA of the display module DM. The transmission region TA may be an optically transparent region. For example, the transmission region TA may have a transmittance of about 90% or greater with respect to the wavelength of visible light ranges. The image IM may be provided to users through the transmission region TA, and the users may receive information through the image IM.

The bezel region BZA may be a portion having a relatively lower light transmittance than the transmission region TA. The bezel region BZA may define a shape of the transmission region TA. The bezel region BZA may be adjacent to the transmission region TA and may surround the transmission region TA.

The bezel region BZA may have a selectable color. The bezel region BZA may cover the peripheral region NAA of the display module DM to prevent the peripheral region NAA from being viewed from the outside. However, this is presented as an example and the bezel region BZA may be omitted in the window WM according to an embodiment.

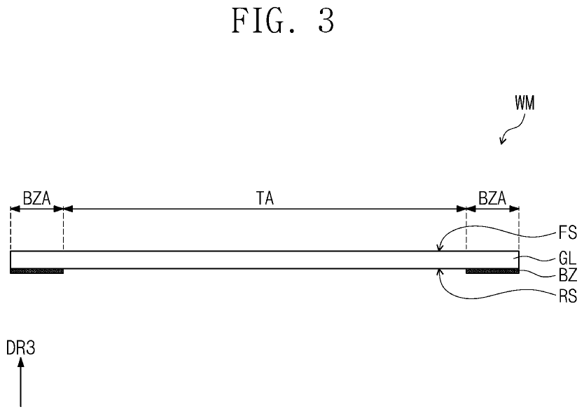

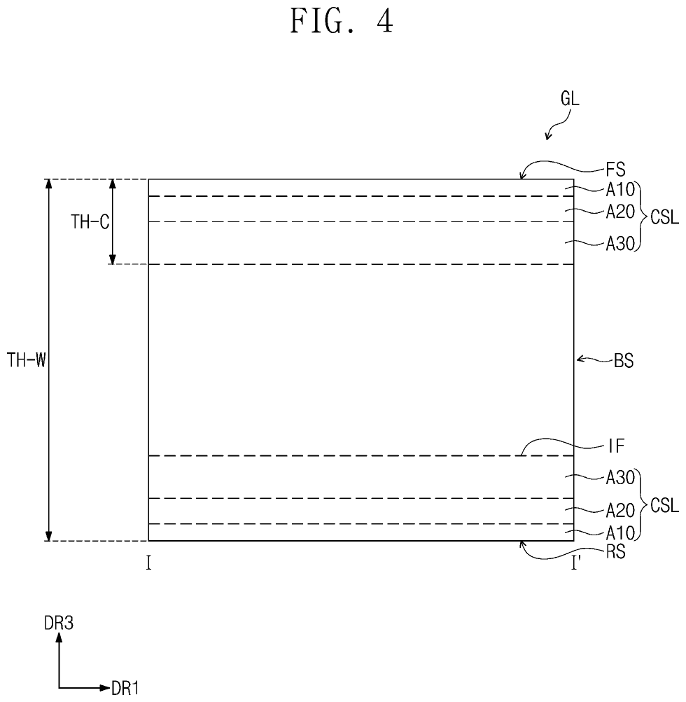

FIG. 3 is a schematic cross-sectional view showing a window according to an embodiment. The window WM may include a strengthened glass substrate GL, and the strengthened glass substrate GL may include Na⁺ ions, K⁺ ions, and Rb⁺ ions. The strengthened glass substrate GL may further include Li⁺ ions. The strengthened glass substrate GL may be strengthened through a method of manufacturing a window of an embodiment, which will be described later. In an embodiment, the window WM including the strengthened glass substrate GL may include a strengthened glass substrate GL in which at least some of the Li⁺ ions included in a preliminary glass substrate are replaced with Na⁺ ions, and at least some of Na⁺ ions included in a preliminary glass substrate are replaced with K⁺ ions and Rb⁺ ions. Accordingly, the strengthened glass substrate GL including Na⁺ ions, K⁺ ions, and Rb⁺ ions may exhibit improved compressive stress. The strengthened glass substrate GL may have a compressive stress layer CSL (see FIG. 4) having a great depth, which is formed through ion exchange to exhibit improved compressive stress on a surface and inside thereof as well. Accordingly, a window WM including the strengthened glass substrate GL may exhibit excellent strength.

Referring to FIG. 3, the strengthened glass substrate GL may include an upper surface FS and a lower surface RS facing the upper surface FS. The upper surface FS of the strengthened glass substrate GL may be exposed to the outside of the display device DD, and may define an upper surface of the window WM and an upper surface of the display device DD.

The window WM may further include a printing layer BZ disposed on the lower surface RS of the strengthened glass substrate GL. The printing layer BZ may be formed on the lower surface RS of the strengthened glass substrate GL through a process of printing or deposition, and the printing layer BZ may be directly disposed on the lower surface RS of the strengthened glass substrate GL.

The printing layer BZ may be disposed on the lower surface RS of the strengthened glass substrate GL to define the bezel region BZA. The printing layer BZ may have a relatively lower light transmittance than the strengthened glass substrate GL. For example, the printing layer BZ may have a selectable color. Accordingly, the printing layer BZ may selectively transmit/reflect only light of a selectable color. The printing layer BZ may be a light blocking layer absorbing incident light. The light transmittance and color of the printing layer BZ may be variously provided according to type and shape of the display device DD.

FIG. 4 is a schematic cross-sectional view showing components of a window according to an embodiment. FIG. 4 is a view showing a portion corresponding to line I-I′ of FIG. 2. FIG. 4 shows a strengthened glass substrate GL in more detail in the window WM according to an embodiment.

The window WM may include the strengthened glass substrate GL including Na⁺ ions, K⁺ ions, and Rb⁺ ions. The strengthened glass substrate GL may further include Li⁺ ions. The strengthened glass substrate GL may be glass including an alumino-silicate skeleton formed from Al₂O₃ and SiO₂. The strengthened glass substrate GL may be formed by strengthening lithium alumino-silicate (LAS) glass including Li⁺ ions in the alumino-silicate skeleton. By way of example, the strengthened glass substrate GL may be formed by strengthening ceramic glass or sapphire glass including Li⁺ ions. The strengthened glass substrate GL may be ultra-thin glass (UTG™) manufactured by strengthening base glass including Li⁺ ions.

The window WM formed through the method of manufacturing a window according to an embodiment may include a compressive stress layer CSL having different compressive stress values according to depth. The window WM according to an embodiment may be formed through a method of manufacturing a window according to an embodiment which will be described later. Regarding the Na⁺ ions, K⁺ ions, and Rb⁺ ions included in the strengthened glass substrate GL, concentrations of each of the Na⁺ ions, K⁺ ions, and Rb⁺ ions according to depth of the strengthened glass substrate GL may be different.

The strengthened glass substrate GL according to an embodiment may include a base layer BS and a compressive stress layer CSL. The compressive stress layer CSL may be disposed on at least one of an upper surface or a lower surface of the base layer BS, and FIG. 4 shows that the compressive stress layer CSL is disposed on both the upper surface and the lower surface of the base layer BS. However, this is an example, and the compressive stress layer CSL may be disposed only on one of the upper surface of the base layer BS or the lower surface of the base layer BS. The upper surface of the base layer BS and the lower surface of the base layer BS may face each other with respect to the third direction DR3.

The base layer BS and the compressive stress layer CSL may be in contact. The base layer BS may have a compressive stress value of zero. The compressive stress layer CSL may be defined as a layer having a compressive stress value exceeding zero. The compressive stress may be zero at an interface IF where the base layer BS and the compressive stress layer CSL are in contact.

With respect to 100% of a total thickness TH-W of the strengthened glass substrate GL, the compressive stress layer CSL may have a thickness TH-C in a range of about 13% to about 25%. For example, with respect to 100% of the total thickness TH-W of the strengthened glass substrate GL, the compressive stress layer CSL may have a thickness TH-C in a range of about 17% to about 25%. By way of example, with respect to 100% of the total thickness TH-W of the strengthened glass substrate GL, the compressive stress layer CSL may have a thickness TH-C of about greater than about 17% and about 25% or less.

The strengthened glass substrate GL may have a thickness TH-W in a range of about 500 μm to about 700 μm. The compressive stress layer CSL may have a thickness TH-C in a range of about 90 μm to about 130 μm. The window WM including the compressive stress layer CSL having a thickness in a range of about 13% to about 25% with respect to 100% of the total thickness TH-W of the strengthened glass substrate GL may exhibit excellent strength. On the other hand, with respect to 100% of the total thickness of the glass substrate, a window including a compressive stress layer having a thickness of less than about 13% exhibits small strength, and the window exhibits properties vulnerable to external shocks. A window including a compressive stress layer of greater than about 25% with respect to 100% of the total thickness of glass substrate may not be obtainable with regard to processes.

The compressive stress layer CSL may include a first region A10 having a first compressive stress change rate, a second region A20 having a second compressive stress change rate, and a third region A30 having a third compressive stress change rate. The first compressive stress change rate may be greater than the second compressive stress change rate, and the second compressive stress change rate may be greater than the third compressive stress change rate.

The first region A10 may be a region disposed on the upper surface FS of the strengthened glass substrate GL and/or the lower surface RS of the strengthened glass substrate GL. For example, the first region A10 may be a region exposed on a surface of the strengthened glass substrate GL. The third region A30 may be a region adjacent to the base layer BS. A separate region is not defined between the third region A30 and the base layer BS, and one surface or a surface of the third region A30 and one surface or a surface of the base layer BS may be in contact. The second region A20 may be provided between the first region A10 and the third region A30. The second region A20 may be spaced apart from the base layer BS with the third region A30 therebetween. The first region A10 may be spaced apart from the base layer BS with the second region A20 and the third region A30 therebetween.

Each of the first compressive stress change rate, the second compressive stress change rate, and the third compressive stress change rate may be defined as a compressive stress change rate according to depth with respect to a thickness direction (for example, the third direction DR3). The compressive stress change rate herein may be defined as a compressive stress change rate according to depth with respect to the thickness direction. For example, in a graph in which the depth is a horizontal axis and the compressive stress is a vertical axis, the compressive stress change rate may be defined as an absolute value of a slope. In the graph in which the depth is a horizontal axis and the compressive stress is a vertical axis, change in compressive stress according to change in depth may be defined as a compressive stress change rate. A point having a horizontal axis value of zero may be the upper surface FS or the lower surface RS of the strengthened glass substrate GL. For example, a point having a horizontal axis value of zero may correspond to the surface of the strengthened glass substrate GL.

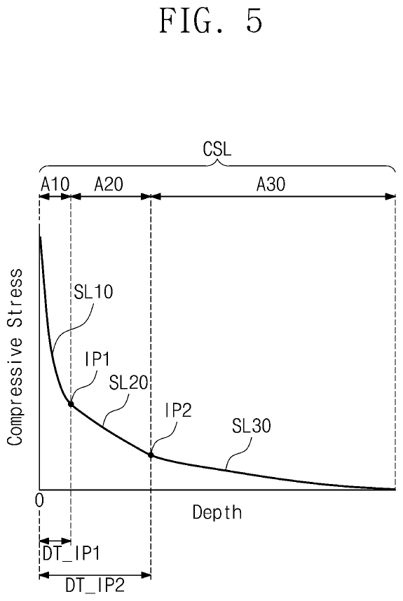

FIG. 5 is a graph schematically showing compressive stress according to depth in a compressive stress layer according to an embodiment. In FIG. 5, the vertical axis is value of compressive stress, the horizontal axis is depth indicated with respect to the thickness direction, and the point having a depth of zero is the upper surface FS or the lower surface RS of the strengthened glass substrate GL.

Referring to FIGS. 4 and 5 together, the depth may increase in the order of the first region A10, the second region A20, and the third region A30, and the compressive stress value may decrease in the order of the first region A10, the second region A20, and the third region A30. The value of the compressive stress in the first region A10 may be greater than the value of the compressive stress in the second region A20 and the value of the compressive stress in the third region A30. The value of the compressive stress in the third region A30 may be smaller than the value of the compressive stress in the first region A10 and the value of the compressive stress in the second region A20. In FIG. 5, a region deeper than the first region A10 may correspond to the base layer BS (FIG. 4). For example, the strengthened glass substrate GL according to an embodiment may include a compressive stress layer CSL having a greatest compressive stress value on the surface thereof and having decreasing compressive stress as getting closer to the base layer BS.

The first region A10 may have a first slope SL10 in the graph of compressive stress according to depth. The first slope SL10 corresponds to the first compressive stress change rate of the first region A10. The first slope SL10 may indicate an instantaneous rate of change of any one point in the first region A10 shown in FIG. 5. For example, the first slope SL10 may be a tangential slope of any one point in the first region A10 shown in FIG. 5.

The second region A20 may have a second slope SL20 in the graph of compressive stress according to depth. The second slope SL20 corresponds to the second compressive stress change rate of the second region A20. The second slope SL20 may indicate an instantaneous rate of change of any one point in the second region A20 shown in FIG. 5. For example, the second slope SL20 may be a tangential slope of any one point in the second region A20 shown in FIG. 5.

The third region A30 may have a third slope SL30 in the graph of compressive stress according to depth. The third slope SL30 corresponds to the third compressive stress change rate of the third region A30. The third slope SL30 may indicate an instantaneous rate of change of any one point in the third region A30 shown in FIG. 5. For example, the third slope SL30 may be a tangential slope of any one point in the third region A30 shown in FIG. 5.

The absolute value of the first slope SL10 of the first region A10 may be greater than the absolute value of the second slope SL20 of the second region A20. The absolute value of third slope SL30 of the third region A30 may be greater than the absolute value of the second slope SL20 of the second region A20. For example, the strengthened glass substrate GL according to an embodiment may include a compressive stress layer CSL having a greatest compressive stress change rate on the surface thereof and having decreasing compressive stress change rate as getting closer to the base layer BS.

Inflection points IP1 and IP2 may be defined between the first region A10 and the second region A20 and between the second region A20 and the third region A30, respectively. As shown in FIG. 5, the inflection points IP1 and IP2 are provided between each of the first region A10, the second region A20, and the third region A30, and may indicate points having a great change in compressive stress change rate. For example, the inflection points IP1 and IP2 may indicate points having a raid change in slope in the compressive stress graph according to depth shown in FIG. 5. The first inflection point IP1 is defined between the first region A10 and the second region A20, and each of the first region A10 and the second region A20 may have a great change in compressive stress change rate before and after the first inflection point IP1. For example, in the first region A10, substantially, as shown in FIG. 5, the compressive stress change rate according to depth has the first slope SL10, and may be changed such that compressive stress has the second slope SL20 according to depth upon passing through the first inflection point IP1 and entering the second region A20. The second inflection point IP2 is defined between the second region A20 and the third region A30, and each of the second region A20 and the third region A30 may have a great change in compressive stress change rate before and after the second inflection point IP2. For example, in the second region A20, substantially, as shown in FIG. 5, the compressive stress change rate according to depth has the second slope SL20, and may be changed such that compressive stress has the third slope SL30 according to depth upon passing through the second inflection point IP2 and entering the third region A30.

In the compressive stress layer CSL included in the strengthened glass substrate GL of an embodiment, the first compressive stress change rate may be at least 5 times the second compressive stress change rate. The second compressive stress change rate may be at least 3 times the third compressive stress change rate. For example, the first slope SL10 shown in FIG. 5 may be about at least 5 times the second slope SL20. For example, the second slope SL20 shown in FIG. 5 may be about at least 3 times the third slope SL30. The first slope SL10 may be about at least 5 times to about at least 9 times the second slope SL20. The second slope SL20 may be about at least 3 times to about at least 7 times the third slope SL30. In an embodiment, the first slope SL10 may be in a range of about 70 MPa/μm to about 100 MPa/μm, the second slope SL20 may be in a range of about 8 MPa/μm to about 15 MPa/μm, and the third slope SL30 may be in a range of about 1.5 MPa/μm to about 4 MPa/μm. However, this is presented as an example, and the value of the first slope SL10 in the first region A10, the value of the second slope SL20 in the second region A20, and the value of the third slope SL30 in the third region A30 are not limited thereto.

Compressive stress measured through a method of ASTM C770-16 in the first inflection point IP1 may be about 400 MPa or greater. Compressive stress measured through the method of ASTM C770-16 in the first inflection point IP1 may be less than about 600 MPa.

The first inflection point IP1 may have a minimum depth DT_IP1 in a range of about 5 μm to about 15 μm. The minimum depth DT_IP1 of the first inflection point IP1 may be defined as a minimum depth from the surface of the window WM to the first inflection point IP1 in the thickness direction (for example, the third direction DR3). The first inflection point IP1 may have a minimum depth of, for example, in a range of about 7 μm to about 12 μm. The surface of the window WM may correspond to a point having a depth of zero in FIG. 5, and the surface of the window WM may be the upper surface FS (FIG. 3) of the strengthened glass substrate GL or the lower surface RS (FIG. 3) of the strengthened glass substrate GL.

The minimum depth DT_IP1 of the first inflection point IP1 may be the same as the thickness of the first region A10. For example, in case that the minimum depth DT_IP1 of the first inflection point IP1 is about 10 m, the region having a depth in a range of about 0 μm to about 10 μm may be the first region A10.

A maximum value of the compressive stress in the first region A10 may be about 1000 MPa to about 1400 MPa, and the compressive stress may be measured through a method of ASTM C770-16. The maximum value of the compressive stress in the first region A10 may be a compressive stress value at a point having a depth of zero. The compressive stress value decreases as the depth of the compressive stress layer increases, and the maximum value of the compressive stress in the first region A10 may thus be a maximum value of the compressive stress throughout the compressive stress layer CSL. In FIG. 5, the point having a depth of zero may have a compressive stress of about 1000 MPa to about 1400 MPa. The compressive stress on the surface (for example, the upper surface FS and/or the lower surface RS) of the strengthened glass substrate GL may be about 1000 MPa to about 1400 MPa.

Compressive stress measured through a method of ASTM C770-16 in the second inflection point IP2 may be about 140 MPa or greater. Compressive stress measured through the method of ASTM C770-16 in the first inflection point IP1 may be less than about 350 MPa.

The second inflection point IP2 may have a minimum depth DT_IP2 in a range of about 20 μm to about 40 μm. The minimum depth DT_IP2 of the second inflection point IP2 may be defined as a minimum depth from the surface of the window WM to the second inflection point IP2 in the thickness direction (for example, the third direction DR3). The second inflection point IP2 may have a minimum depth of, for example, in a range of about m to about 35 μm.

The minimum depth DT_IP2 of the second inflection point IP2 may be the same as the thickness of the first region A10 and the second region A20. For example, in case that the minimum depth DT_IP2 of the second inflection point IP2 is about 30 m, the region having a depth in a range of about 0 μm to about 30 μm may be the first region A10 and the second region A20.

In the compressive stress layer CSL, a point having a depth of about 30 m may have a compressive stress of about 100 MPa or greater as measured through the method of ASTM C770-16. In the compressive stress layer CSL, a point having a depth of about 30 m may have a compressive stress of about 140 MPa or greater as measured through the method of ASTM C770-16. The point having a depth of about 30 μm in the compressive stress layer CSL may be a portion where the second inflection point IP2 is defined or may be included in the second region A20. For example, at the point where the depth of the compressive stress layer CSL is about 30 m, the compressive stress may be about 180 MPa to about 300 MPa.

In the compressive stress layer CSL, a point having a depth of about 50 m may have a compressive stress of about 80 MPa or greater as measured through the method of ASTM C770-16. The point having a depth of about 50 μm in the compressive stress layer CSL may be included in the third region A30. For example, at the point where the depth of the compressive stress layer CSL is about 50 m, the compressive stress may be about 100 MPa to about 200 MPa.

As the compressive stress value in the compressive stress layer CSL according to an embodiment satisfies a selectable range, the window WM including the compressive stress layer CSL may exhibit improved strength. The display device DD including the window WM according to an embodiment may exhibit excellent reliability.

The window according to an embodiment may be formed through a method of manufacturing a window according to an embodiment, which will be described later.

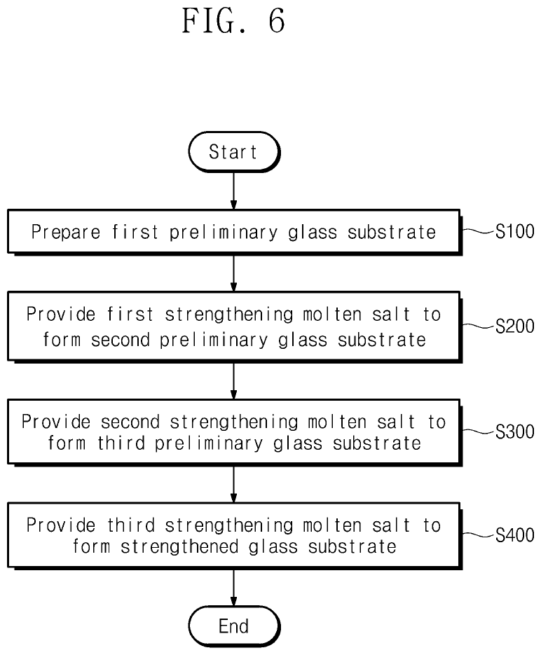

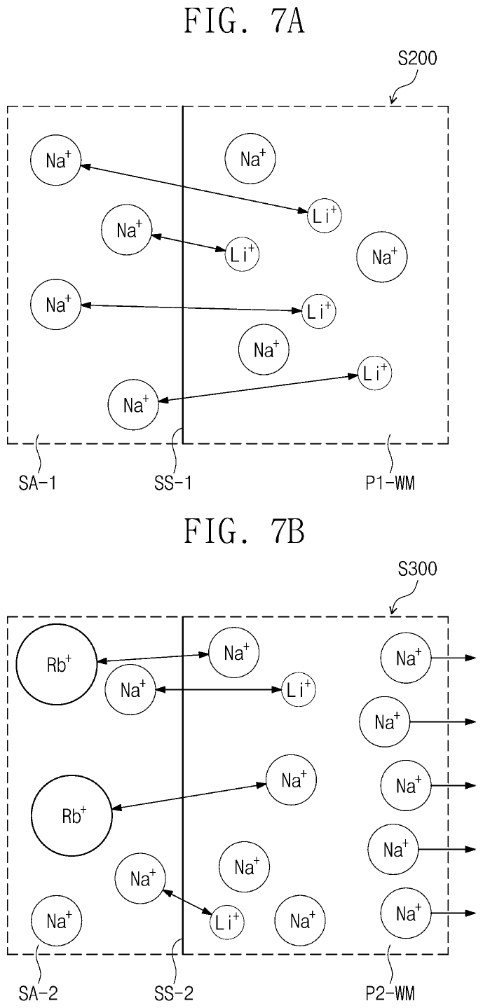

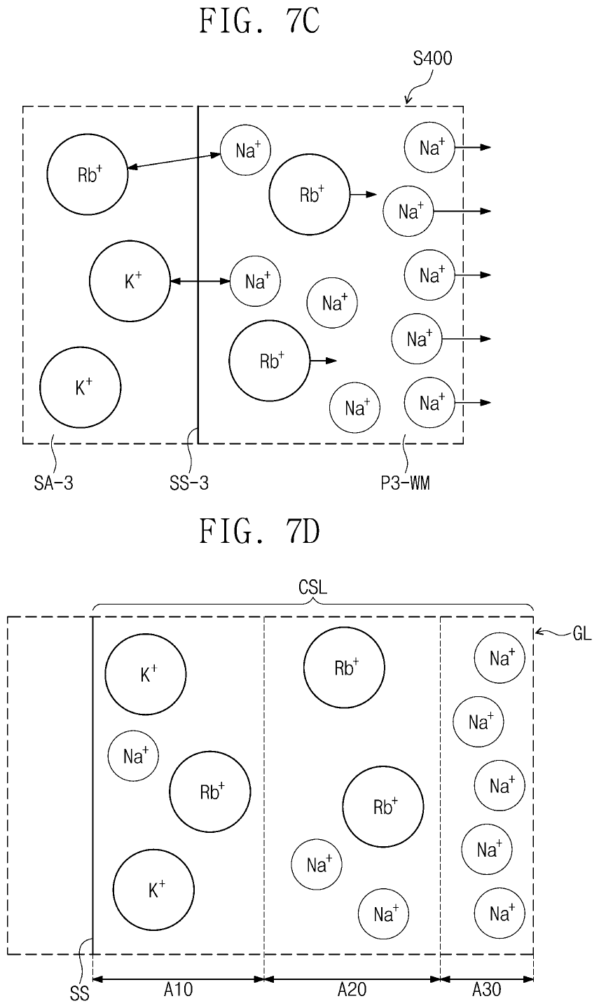

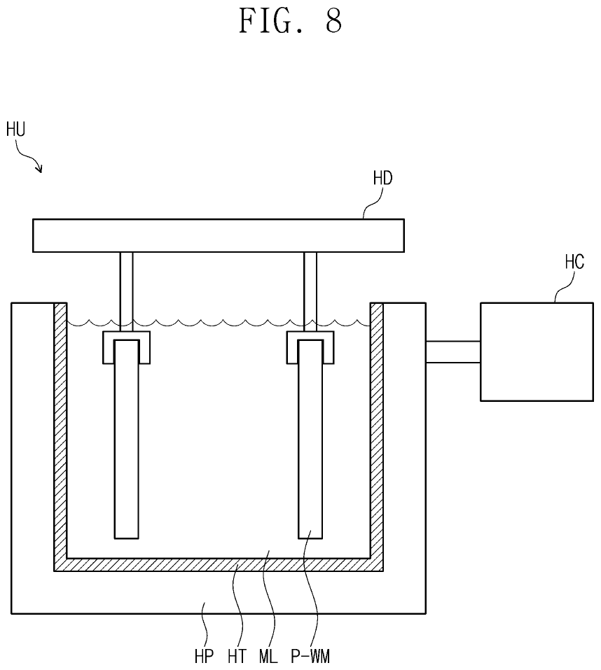

FIG. 6 is a flowchart showing a method of manufacturing a display device of an embodiment. FIGS. 7A to 7D schematically show stages in a method of manufacturing a window of an embodiment. FIG. 8 schematically shows a window manufacturing device that performs stages of a method of manufacturing a window in a process of a method of manufacturing a window of an embodiment. Hereinafter, in descriptions of the method of manufacturing a window according to an embodiment with reference to FIGS. 6 and 8, content overlapping the one described above with reference to FIGS. 1 to 5 will not be described again, and the differences will be described.

The method of manufacturing a window according to an embodiment may include preparing a first preliminary glass substrate (S100), forming a second preliminary glass substrate from the first preliminary glass substrate (S200), forming a third preliminary glass substrate from the second preliminary glass substrate (S300), and forming a strengthened glass substrate from the third preliminary glass substrate (S400). The method of manufacturing a window according to an embodiment may further include cleaning and/or cooling respectively between the forming of the second preliminary glass substrate (S200) and the forming of the third preliminary glass substrate (S300), between the forming of the third preliminary glass substrate (S300) and the forming of the window from the third preliminary glass substrate (S400), and after the forming of the strengthened glass substrate (S400).

FIGS. 7A to 7D schematically show movement of ions in each stage of the method of manufacturing a window according to an embodiment. FIG. 7A shows a stage (S200) of providing a first strengthening molten salt SA-1 onto a first preliminary glass substrate P1-WM to form a second preliminary glass substrate P2-WM (see FIG. 7B).

The first preliminary glass substrate P1-WM may be glass including an alumino-silicate skeleton formed from Al₂O₃ and SiO₂. The first preliminary glass substrate P1-WM may be glass including Li⁺ ions. The first preliminary glass substrate P1-WM may be lithium alumino-silicate (LAS) glass in which Li⁺ ions are included in the alumino-silicate skeleton. By way of example, the first preliminary glass substrate P1-WM may be ceramic glass or sapphire glass including Li⁺ ions. The first preliminary glass substrate P1-WM may further include Na⁺ ions. The first preliminary glass substrate P1-WM may further include at least one of K⁺ ions or Mg²⁺ ions.

Referring to FIGS. 6, 7A, and 7B together, the method of manufacturing a window according to an embodiment may include forming a second preliminary glass substrate from the first preliminary glass substrate (S200). The second preliminary glass substrate P2-WM may be formed by providing the first strengthening molten salt SA-1 onto the first preliminary glass substrate P1-WM. The first strengthening molten salt SA-1 may be provided at a temperature of about 380° C. to about 420° C. for about 30 minutes to 3 hours.

The first strengthening molten salt SA-1 may include NaNO₃. The first strengthening molten salt SA-1 may include Na⁺ ions. The first strengthening molten salt SA-1 may include only Na⁺ ions as cations. With respect to a total cation concentration of the first strengthening molten salt SA-1, the first strengthening molten salt SA-1 may include Na⁺ ions at a proportion of about 100%.

On a surface SS-1 of the first preliminary glass substrate P1-WM, Na⁺ ions of the first strengthening molten salt SA-1 may be exchanged with Li⁺ ions included in the first preliminary glass substrate P1-WM. In the providing of the first strengthening molten salt SA-1, Na⁺ ions having a relatively large ionic radius and Li⁺ ions having a relatively small ionic radius may be exchanged. For example, Li⁺ ions having a small ionic radius included in the first preliminary glass substrate P1-WM may be exchanged for Na⁺ ions having a larger ionic radius.

Accordingly, Na⁺ ions of the first strengthening molten salt SA-1 may move into the first preliminary glass substrate P1-WM. The surface SS-1 of the first preliminary glass substrate P1-WM may include an upper surface and/or a lower surface of the first preliminary glass substrate P1-WM. The surface SS-1 of the first preliminary glass substrate P1-WM may include an outer surface of the first preliminary glass substrate P1-WM, which is exposed to the outside.

Na⁺ ions included in the first strengthening molten salt SA-1 may be provided to form the compressive stress layer CSL having a greater thickness (FIG. 4). Compared to the case where the first strengthening molten salt does not include Na⁺ ions, in case that the first strengthening molten salt SA-1 may include Na⁺ ions, the compressive stress layer CSL having a greater thickness (FIG. 4) may be formed. Na⁺ ions included in the first strengthening molten salt SA-1 may move into a glass substrate in subsequent processes performed sequentially after the providing of the first strengthening molten salt SA-1 to form a thick compressive stress layer CSL (FIG. 4).

Li⁺ ions of the first preliminary glass substrate P1-WM may be exchanged for Na⁺ ions to form the second preliminary glass substrate P2-WM. The second preliminary glass substrate P2-WM having a greater concentration of Na⁺ ions in the glass substrate as a result of exchanging Li⁺ ions for Na⁺ ions may have a greater compressive stress of a surface SS-2 than the compressive stress of the surface SS-1 of the first preliminary glass substrate P1-WM. Na⁺ ions move into the second preliminary glass substrate P2-WM, and the compressive stress inside a selectable depth of the second preliminary glass substrate P2-WM may thus be greater than the compressive stress inside the first preliminary glass substrate P1-WM.

FIG. 7B shows a stage (S300) of providing a second strengthening molten salt SA-2 onto the second preliminary glass substrate P2-WM to form a third preliminary glass substrate P3-WM (see FIG. 7C).

The second preliminary glass substrate P2-WM may be a glass substrate for example strengthened through the providing of the first strengthening molten salt SA-1 described above to have strengthened compressive stress on a surface and a portion of an inner side. The second preliminary glass substrate P2-WM may include Na⁺ ions. The second preliminary glass substrate P2-WM may further include remaining Li⁺ ions that are not exchanged in the providing of the first strengthening molten salt SA-1. The second preliminary glass substrate P2-WM may further include at least one of K⁺ ions or Mg²⁺ ions.

Referring to FIGS. 6, 7B, and 7C together, the method of manufacturing a window according to an embodiment may include forming a third preliminary glass substrate from the second preliminary glass substrate (S300). In the method of manufacturing a window of an embodiment, the third preliminary glass substrate P3-WM may be formed by providing a second strengthening molten salt SA-2 onto the second preliminary glass substrate P2-WM. The second strengthening molten salt SA-2 may be provided at a temperature of about 380° C. to about 420° C. for about 30 minutes to about 3 hours.

The second strengthening molten salt SA-2 may include NaNO₃ and RbNO₃. The second strengthening molten salt SA-2 may include Na⁺ ions and Rb⁺ ions. The second strengthening molten salt SA-2 may include Na⁺ ions and Rb⁺ ions as cations, but may not include other cations. With respect to a total cation concentration of the second strengthening molten salt SA-2, the second strengthening molten salt SA-2 may include Na⁺ ions at a proportion in a range of about 60% to about 90%, and Rb⁺ ions at a proportion in a range of about 10% to about 40%. For example, the second strengthening molten salt SA-2 may include Na⁺ ions at a proportion of about 70% and Rb⁺ ions at a proportion of about 30%.

On a surface SS-2 of the second preliminary glass substrate P2-WM, Na⁺ ions of the second strengthening molten salt SA-2 may be exchanged with Li⁺ ions included in the second preliminary glass substrate P2-WM. In the providing of the second strengthening molten salt SA-2, Na⁺ ions having a relatively large ionic radius and Li⁺ ions having a relatively small ionic radius may be exchanged. For example, Li⁺ ions having a small ionic radius included in the second preliminary glass substrate P2-WM may be exchanged for Na⁺ ions having a larger ionic radius.

On the surface SS-2 of the second preliminary glass substrate P2-WM, Rb⁺ ions of the second strengthening molten salt SA-2 may be exchanged with Na⁺ ions included in the second preliminary glass substrate P2-WM. In the providing of the second strengthening molten salt SA-2, Rb⁺ ions having a relatively large ionic radius and Na⁺ ions having a relatively small ionic radius may be exchanged. For example, Na⁺ ions having a small ionic radius included in the second preliminary glass substrate P2-WM may be exchanged for Rb⁺ ions having a larger ionic radius. Although not shown in FIG. 7B, Rb⁺ ions of the second strengthening molten salt SA-2 may be exchanged with Li⁺ ions included in the second preliminary glass substrate P2-WM.

Accordingly, Na⁺ ions and Rb⁺ ions of the second strengthening molten salt SA-2 may move into the second preliminary glass substrate P2-WM. The surface SS-2 of the second preliminary glass substrate P2-WM may include an upper surface and/or a lower surface of the second preliminary glass substrate P2-WM. The surface SS-2 of the second preliminary glass substrate P2-WM may include an outer surface of the second preliminary glass substrate P2-WM, which is exposed to the outside.

Na⁺ ions included in the second strengthening molten salt SA-2 may be provided to form the compressive stress layer CSL having a greater thickness (FIG. 4). Compared to a case where the second strengthening molten salt does not include Na⁺ ions, in case that the second strengthening molten salt SA-2 may include Na⁺ ions, the compressive stress layer CSL having a greater thickness (FIG. 4) may be formed. Na⁺ ions included in the second strengthening molten salt SA-2 may move into a glass substrate in subsequent processes performed sequentially after the providing of the second strengthening molten salt SA-2 to form a thick compressive stress layer CSL (FIG. 4).

Rb⁺ ions included in the second strengthening molten salt SA-2 may be provided to improve compressive stress inside a glass substrate. Compared to a case where the second strengthening molten salt does not include Rb⁺ ions, in case that the second strengthening molten salt SA-2 may include Rb⁺ ions, the compressive stress of the second region A20 (see FIG. 4) disposed inside of the compressive stress layer CSL (FIG. 4) may be improved. Rb⁺ ions included in the second strengthening molten salt SA-2 may move into a glass substrate in subsequent processes after the providing of the second strengthening molten salt SA-2 to improve the compressive stress inside the glass substrate.

Some of the Li⁺ ions and Na⁺ ions of the second preliminary glass substrate P2-WM may be exchanged for Na⁺ ions and Rb⁺ ions included in the second strengthening molten salt SA-2 to form a third preliminary glass substrate P3-WM. The third preliminary glass substrate P3-WM having a greater concentration of Na⁺ ions and Rb⁺ ions in the glass substrate as a result of exchanging some of Li⁺ ions and Na⁺ ions for Na⁺ ions and Rb⁺ ions may have a greater compressive stress of a surface SS-3 than the compressive stress of the surface SS-2 of the second preliminary glass substrate P2-WM. Some of Rb⁺ ions and Na⁺ ions move into the third preliminary glass substrate P3-WM, and the compressive stress inside a selectable depth of the third preliminary glass substrate P3-WM may thus be greater than the compressive stress inside the second preliminary glass substrate P2-WM.

FIG. 7C shows a stage (S400) of providing a third strengthening molten salt SA-3 to the third preliminary glass substrate P3-WM to form a strengthened glass substrate GL (see FIG. 7D). FIG. 7D shows a portion of a cross-section of the strengthened glass substrate GL formed after the providing of the third strengthening molten salt SA-3.

The third preliminary glass substrate P3-WM may be a glass substrate for example strengthened through the providing of the first strengthening molten salt SA-1 and the providing of the second strengthening molten salt SA-2 described above to have strengthened compressive stress on a surface and a portion of an inner side. The third preliminary glass substrate P3-WM may include Na⁺ ions and Rb⁺ ions. The third preliminary glass substrate P3-WM may further include remaining Li⁺ ions that are not exchanged in the providing of the first strengthening molten salt SA-1 and the providing of the second strengthening molten salt SA-2. The third preliminary glass substrate P3-WM may further include at least one of K⁺ ions or Mg²⁺ ions.

Referring to FIGS. 6, 7C, and 7D together, the method of manufacturing a window according to an embodiment may include forming a strengthened glass substrate from the third preliminary glass substrate (S300). In the method of manufacturing a window of an embodiment, the strengthened glass substrate GL may be formed by providing a third strengthening molten salt SA-3 to the third preliminary glass substrate P3-WM. The third strengthening molten salt SA-3 may be provided at a temperature of about 380° C. to about 450° C. for about 10 minutes to about 2 hours.

In an embodiment, the third strengthening molten salt SA-3 may include at least one of KNO₃, KCl, or K₂SO₄. The third strengthening molten salt SA-3 may include K⁺ ions and Rb⁺ ions. The third strengthening molten salt SA-3 may include K⁺ ions and Rb⁺ ions as cations, but may not include other cations. With respect to a total cation concentration of the third strengthening molten salt SA-3, the third strengthening molten salt SA-3 may include K⁺ ions at a proportion in a range of about 60% to about 90%, and Rb⁺ ions at a proportion in a range of about 10% to about 40%. For example, the third strengthening molten salt SA-3 may include K⁺ ions at a proportion of about 70% and Rb⁺ ions at a proportion of about 30%.

On the surface SS-3 of the third preliminary glass substrate P3-WM, Rb⁺ ions of the third strengthening molten salt SA-3 may be exchanged with Na⁺ ions included in the third preliminary glass substrate P3-WM. In the providing of the third strengthening molten salt SA-3, Rb⁺ ions having a relatively large ionic radius and Na⁺ ions having a relatively small ionic radius may be exchanged. For example, Na⁺ ions having a small ionic radius included in the third preliminary glass substrate P3-WM may be exchanged for Rb⁺ ions having a larger ionic radius.

On the surface SS-3 of the third preliminary glass substrate P3-WM, K⁺ ions of the third strengthening molten salt SA-3 may be exchanged with Na⁺ ions included in the third preliminary glass substrate P3-WM. In the providing of the third strengthening molten salt SA-3, K⁺ ions having a relatively large ionic radius and Na⁺ ions having a relatively small ionic radius may be exchanged. For example, K⁺ ions having a small ionic radius included in the third preliminary glass substrate P3-WM may be exchanged for Rb⁺ ions having a larger ionic radius. Although not shown in FIG. 7B, Rb⁺ ions and K⁺ ions of the third strengthening molten salt SA-3 may be exchanged with Li⁺ ions remaining on the third preliminary glass substrate P3-WM. By way of example, each of Rb⁺ ions and K⁺ ions of the third strengthening molten salt SA-3 may be exchanged with each of Rb⁺ ions and K⁺ ions included in the third preliminary glass substrate P3-WM.

Accordingly, K⁺ ions and Rb⁺ ions of the third strengthening molten salt SA-3 may move into the third preliminary glass substrate P3-WM. The surface SS-3 of the third preliminary glass substrate P3-WM may include an upper surface and/or a lower surface of the third preliminary glass substrate P3-WM. The surface SS-3 of the third preliminary glass substrate P3-WM may include an outer surface of the third preliminary glass substrate P3-WM, which is exposed to the outside.

K⁺ ions and Rb⁺ ions included in the third strengthening molten salt SA-3 may be provided to improve compressive stress inside a glass substrate. Compared to a case where the third strengthening molten salt does not include K⁺ ions and Rb⁺ ions, in case that the third strengthening molten salt SA-3 may include K⁺ ions and Rb⁺ ions, the compressive stress of the first region A10 (see FIG. 4) disposed on a surface of the compressive stress layer CSL (see FIG. 4) may be improved. Some of K⁺ ions and Rb⁺ ions included in the third strengthening molten salt SA-3 may move into a glass substrate in subsequent processes after the providing of the third strengthening molten salt SA-3 to improve the compressive stress inside the glass substrate.

Some of the Na⁺ ions of the third preliminary glass substrate P3-WM may be exchanged for K⁺ ions and Rb⁺ ions included in the third strengthening molten salt SA-3 to form a strengthened glass substrate GL. The strengthened glass substrate GL having a greater concentration of K⁺ ions and Rb⁺ ions in the glass substrate as a result of exchanging some of Na⁺ ions for K⁺ ions and Rb⁺ ions may have a greater compressive stress of a surface SS than the compressive stress of the surface SS-3 of the third preliminary glass substrate P3-WM.

Referring to FIGS. 7A to 7D, Na⁺ ions provided through each of the first strengthening molten salt SA-1 and the second strengthening molten salt SA-2 may be located or disposed on a surface of a glass substrate and also some of Na⁺ ions may move into the glass substrate through the providing of strengthening molten salts to improve compressive stress inside the glass substrate. For example, in the completed strengthened glass substrate GL, some of Na⁺ ions provided through each of the first strengthening molten salt SA-1 and the second strengthening molten salt SA-2 may move to the third region A30 located or disposed at an innermost portion of the compressive stress layer CSL to improve compressive stress of the third region A30. Na⁺ ions may move according to a difference in chemical potential. For example, some of Na⁺ ions provided through each of the first strengthening molten salt SA-1 and the second strengthening molten salt SA-2 may move from a surface having a large number of Na⁺ ions to the inside having a small number of Na⁺ ions.

Rb⁺ ions provided through each of the second strengthening molten salt SA-2 and the third strengthening molten salt SA-3 may be located or disposed on a surface of a glass substrate and also some of Rb⁺ ions may move into the glass substrate through the providing of strengthening molten salts to improve compressive stress inside the glass substrate. For example, in the completed strengthened glass substrate GL, some of Rb⁺ ions provided through each of the second strengthening molten salt SA-2 and the third strengthening molten salt SA-3 may move to the second region A20 located or disposed further inside than the first region A10 of compressive stress layer CSL to improve compressive stress of the second region A20. Rb⁺ ions may move according to a difference in chemical potential. Some of Rb⁺ ions provided through each of the second strengthening molten salt SA-2 and the third strengthening molten salt SA-3 may move from a surface having a large number of Rb⁺ ions to the inside having a small number of Rb⁺ ions.

K⁺ ions provided through the third strengthening molten salt SA-3 may improve compressive stress on a surface of a glass substrate. In the completed strengthened glass substrate GL, K⁺ ions provided through the third strengthening molten salt SA-3 may be located or disposed in the first region A10 of the compressive stress layer CSL to improve compressive stress of the first region A10.

As shown in FIG. 7D, the compressive stress layer CSL of the strengthened glass substrate GL may include a first region A10, a second region A20, and a third region A30, which are sequentially disposed from a surface SS, and each of the first region A10, the second region A20, and the third region A30 may have different cation composition. In an embodiment, Na⁺ ions, K⁺ ions, and Rb⁺ ions may be included in the first region A10. The second region A20 may include Na⁺ ions and Rb⁺ ions. The third region A30 may include Na⁺ ions. However, an embodiment is not limited thereto, and a small amount of K⁺ ions may be further included in the second region A20, and a small amount of K⁺ ions and Rb⁺ ions may be further included in the third region A30. The second region A20 and the third region A30 may each further include Li⁺ ions. In case that a total sum of monovalent alkali ions is expressed as R, in an embodiment, concentration of ions each included in the first region A10 may be provided at a ratio of 20≤Rb⁺/R₂O≤60, K⁺/R₂O≤60, Na⁺/R₂O≤40 with respect to R₂O concentration. Concentration of ions each included in the second region A20 may be provided at a ratio of 0≤Rb⁺/R₂O≤10, K⁺/R₂O≤30, Na⁺/R₂O≤80, Li⁺/R₂O≤20 with respect to R₂O concentration.

As the method of manufacturing a window according to an embodiment provides a strengthening molten salt through three stages, the three stages of ion exchange are performed, and accordingly, a strengthened glass substrate GL manufactured through the method of manufacturing a window according to an embodiment may form a compressive stress layer CSL having a thickness TH-C in a range of about 100 μm to about 130 μm, and to improve compressive stress on a surface and inside of the strengthened glass substrate GL. Accordingly, the window WM (FIG. 2) including the strengthened glass substrate GL formed through the method of manufacturing a window according to an embodiment may exhibit improved strength. The display device DD including the window WM (FIG. 2) formed through the method of manufacturing a window according to an embodiment may include regions having different compressive stress change rates (for example, the first region A10, the second region A20, and the third region A30), and may thus exhibit excellent reliability.

As the method of manufacturing a window according to an embodiment provides a strengthening molten salt through three stages, a compressive stress layer CSL including three regions having different compressive stress change rates may be formed. The third region A30 included in the compressive stress layer CSL may be formed as Na⁺ ions provided through each of the first strengthening molten salt SA-1 and the second strengthening molten salt SA-2 move into the strengthened glass substrate GL through the processes, and as a result of the three-stage ion exchange, the third region A30 may be formed from a surface SS of the strengthened glass substrate GL to a deep portion. The second region A20 may be formed as some of Rb⁺ ions provided through each of the second strengthening molten salt SA-2 and the third strengthening molten salt SA-3 move into the strengthened glass substrate GL through the processes, and may be formed as a region having an intermediate level of compressive stress and an intermediate level of compressive stress change rate between the first region A10 and the third region A30. The first region A10 is a region formed adjacent to the surface SS of the strengthened glass substrate GL, and may be a region having high compressive stress by including Rb⁺ ions and K⁺ ions provided through the third strengthening molten salt SA-3. In the strengthened glass substrate GL formed through the method of manufacturing a window according to an embodiment, a maximum value of compressive stress measured through a method of ASTM C770-16 in a surface may be about 1000 MPa to about 1400 MPa, compressive stress measured through a method of ASTM C770-16 at a depth of about 30 μm from a surface SS of the strengthened glass substrate GL may be about 140 MPa or greater, and compressive stress measured through a method of ASTM C770-16 at a depth of about 50 μm from the surface SS of the strengthened glass substrate GL may be about 80 MPa or greater.

The method of manufacturing a window according to an embodiment may further include forming a printing layer BZ (FIG. 3) on one surface or a surface of the glass substrate GL (FIG. 4). As described above, the printing layer BZ (FIG. 3) may be formed on a lower surface RS of the glass substrate GL (FIG. 4) through a process of printing or deposition.

FIG. 8 schematically shows ion exchange devices performing each stage of forming a second preliminary glass substrate from the first preliminary glass substrate (S200), forming a third preliminary glass substrate from the second preliminary glass substrate (S300), and forming a strengthened glass substrate from the third preliminary glass substrate (S400). In FIG. 8, a preliminary glass substrate P-WM may be the first preliminary glass substrate P1-WM (FIG. 7A), the second preliminary glass substrate P2-WM (FIG. 7B), or the third preliminary glass substrate P3-WM (FIG. 7C).

A strengthening treatment unit HU may be used to provide the first strengthening molten salt SA-1 (FIG. 7A), the second strengthening molten salt SA-2 (FIG. 7B), and the third strengthening molten salt SA-3 (FIG. 7C) onto the preliminary glass substrate P-WM. The preliminary glass substrate P-WM may be immersed in a molten solution ML, using the strengthening treatment unit HU. The molten solution ML may include the first strengthening molten salt SA-1 (FIG. 7A), the second strengthening molten salt SA-2 (FIG. 7B), and the third strengthening molten salt SA-3 (FIG. 7C).

The strengthening treatment unit HU may include a tank HT containing the molten solution ML, a heater HP disposed surrounding the tank HT and applying heat to the molten solution ML in the tank HT, a driver HD fixing and vertically moving the preliminary glass substrate P-WM to immerse the preliminary glass substrate P-WM in the molten solution ML, and a controller HC controlling the operation of the strengthening treatment unit HU. The controller HC may control the temperature of the molten solution ML contained in the tank HT.

For example, the controller HC may control the heater HP to heat the molten solution ML at a selectable temperature and keep the temperature of the molten solution ML at the heated temperature. The heater HP may serve to provide heat to heat the molten solution ML, or serve as a heat insulator to keep the temperature of the heated molten solution ML. The preliminary glass substrate P-WM may be disposed such that the entirety thereof is immersed in the molten solution ML. In FIG. 8, two preliminary glass substrates P-WM are shown to be provided to the strengthening treatment unit HU, but this is presented as an example, and one preliminary glass substrate P-WM, or three preliminary glass substrates P-WM or more may be provided.

The method of manufacturing a window may include providing a first strengthening molten salt to the first preliminary glass substrate including Li⁺ ions to form a second preliminary glass substrate, providing a second strengthening molten salt to the second preliminary glass substrate to form a third preliminary glass substrate, and providing a third strengthening molten salt to the third preliminary glass substrate to form a strengthened glass substrate. The first strengthening molten salt may include Na⁺ ions, the second strengthening molten salt may include at least Rb⁺ ions, and the third strengthening molten salt may include at least K⁺ ions. Accordingly, in a window manufactured through the method of manufacturing a window according to an embodiment, a strengthened glass substrate included in the window may include a deep compressive stress layer from a surface, and compressive stress on the surface and inside may be improved. Accordingly, the window of an embodiment may exhibit improved strength.

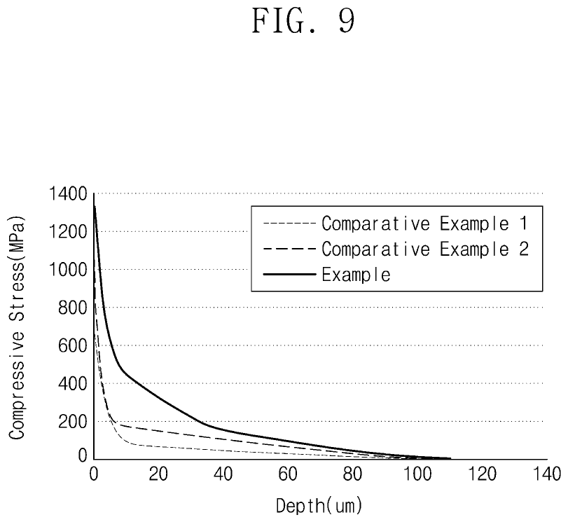

FIG. 9 is a graph showing compressive stress according to depth in a window of Comparative Examples and Examples. In FIG. 9, compressive stress according to depth is measured through a method of ASTM C770-16 using FSM-6000LE of Orihara Industrial Co., Ltd. In the graph of FIG. 9, a point having a depth of zero corresponds to the surface of the window. A window of Example is a window manufactured through three stages of ion exchange (for example, providing a first strengthening molten salt, providing a second strengthening molten salt, and providing a third strengthening molten salt), using Dragontrail™ Star-2 of Asahi Glass as a first preliminary glass substrate. A window of Comparative Example 1 is a window manufactured through two stages of ion exchange (providing a strengthening molten salt including Na⁺ ions, and providing a strengthening molten salt including K⁺ ions), using Gorilla™ Glass 5 of Corning as a first preliminary glass substrate. A window of Comparative Example 2 is a window manufactured through two stages of ion exchange (providing a strengthening molten salt including Na⁺ ions, and providing a strengthening molten salt including K⁺ ions), using Gorilla™ Glass 7 of Corning as a first preliminary glass substrate.

Referring to FIG. 9, it is determined that the window of Example may include two inflection points in a graph of compressive stress according to depth, and thus have greater compressive stress both on a surface and inside than the window of Comparative Example. By way of example, despite the fact that the window of Example is based on Asahi Glass's Dragontrail™ Star-2 substrate, which is a relatively inexpensive glass substrate, the window of Example has greater compressive stress than the windows of Comparative Examples which are based on expensive substrates. It is determined that the window of Example may include a compressive stress layer having a thick thickness by including a point having a compressive stress of zero at a depth of about 110 μm.

The window of an embodiment is manufactured through the manufacturing method including the providing of a strengthening molten salt through three stages as described above, and accordingly, a strengthened glass substrate included in the window may include a deep compressive stress layer from a surface, and compressive stress on the surface and inside may be improved. Accordingly, the window of an embodiment may exhibit improved strength, and a display device including the window of an embodiment may have improved reliability and stability.

A method of manufacturing a window according to an embodiment may include three stages of ion exchange strengthening to manufacture a window according to an embodiment, which exhibits improved strength.

A window according to an embodiment and a display device including the window may exhibit improved strength.

Although the disclosure has been described with reference to embodiments, it will be understood that the disclosure should not be limited to these embodiments but various changes and modifications can be made by those skilled in the art without departing from the spirit and scope of the disclosure. Accordingly, the technical scope is not intended to be limited to the contents set forth in the detailed description of the specification, but is intended to also be defined by the appended claims.

What is claimed is:

1. A method of manufacturing a window, the method comprising:
preparing a first preliminary glass substrate including Li⁺ ions and Na⁺ ions;
providing a first strengthening molten salt including Na⁺ ions onto the first preliminary glass substrate and forming a second preliminary glass substrate;
providing a second strengthening molten salt including Rb⁺ ions onto the second preliminary glass substrate and forming a third preliminary glass substrate; and
providing a third strengthening molten salt including K⁺ ions onto the third preliminary glass substrate and forming a strengthened glass substrate.

2. The method of claim 1, wherein the first strengthening molten salt comprises NaNO₃.

3. The method of claim 1, wherein the second strengthening molten salt comprises Na⁺ ions.

4. The method of claim 3, wherein
the Na⁺ ions are present at a proportion in a range of about 60% to about 90%, and
the Rb⁺ ions are present at a proportion in a range of about 10% to about 40%
with respect to a total cation concentration of the second strengthening molten salt.

5. The method of claim 1, wherein the third strengthening molten salt comprises Rb⁺ ions.

6. The method of claim 5, wherein
the K⁺ ions are present at a proportion in a range of about 60% to about 90%, and
the Rb⁺ ions are present at a proportion in a range of about 10% to about 40% with respect to a total cation concentration of the second strengthening molten salt.

7. The method of claim 1, wherein the first strengthening molten salt is provided at a temperature in a range of about 380° C. to about 420° C. for a period in a range of about 30 minutes to about 3 hours in the forming of the second preliminary glass substrate.

8. The method of claim 1, wherein the second strengthening molten salt is provided at a temperature in a range of about 380° C. to about 420° C. for a period in a range of about 30 minutes to about 3 hours in the forming of the third preliminary glass substrate.

9. The method of claim 1, wherein the third strengthening molten salt is provided at a temperature in a range of about 380° C. to about 450° C. for a period in a range of about 10 minutes to about 2 hours in the forming of the strengthened glass substrate.

10. The method of claim 1, wherein
the strengthened glass substrate comprises a compressive stress layer having a compressive stress of about 1400 MPa or less as measured through a method of ASTM C770-16, and
the compressive stress layer has a thickness in a range of about 90 μm to about 130 μm.

11. The method of claim 1, further comprising:
forming a printing layer overlapping a portion of the strengthened glass substrate in plan view after the forming of the strengthened glass substrate.

12. A window comprising:
a strengthened glass substrate including Na⁺ ions, K⁺ ions, and Rb⁺ ions, wherein
the strengthened glass substrate includes:
a base layer having a compressive stress value of zero; and
a compressive stress layer disposed on at least one of an upper surface or a lower surface of the base layer,
the compressive stress layer including:
a first region having a first compressive stress change rate;
a second region having a second compressive stress change rate less than the first compressive stress change rate; and
a third region having a third compressive stress change rate less than the second compressive stress change rate,
each of the first compressive stress change rate, the second compressive stress change rate and the third compressive stress change rate are a compressive stress change rate according to depth with respect to a thickness direction,
a minimum depth from a surface of the strengthened glass substrate to a border between the first region and the second region is in a range of about 5 μm to about 15 μm with respect to the thickness direction,
a minimum depth from a surface of the strengthened glass substrate to a border between the second region and the third region is in a range of about 20 μm to about 40 m with respect to the thickness direction, and
the compressive stress layer has a thickness in a range of about 100 μm to about 130 μm.

13. The window of claim 12, wherein the first region is spaced apart from the base layer with the second region and the third region disposed between the first region and the base layer.

14. The window of claim 12, wherein the compressive stress layer has a thickness in a range of about 13% to about 25% with respect to 100% of a total thickness of the strengthened glass substrate.

15. The window of claim 12, wherein the strengthened glass substrate has a thickness in a range of about 500 μm to about 700 μm.

16. The window of claim 12, wherein
an upper surface of the first region defines a surface of the strengthened glass substrate, and
a maximum value of compressive stress measured through a method of ASTM C770-16 in the surface is in a range of about 1000 MPa to about 1400 MPa.

17. The window of claim 12, wherein compressive stress through a method of ASTM C770-16 at the border between the second region and the third region is about 140 MPa or greater.

18. The window of claim 12, wherein compressive stress measured through a method of ASTM C770-16 at a depth of about 30 μm from the surface of the strengthened glass substrate is about 140 MPa or greater with respect to the thickness direction.

19. The window of claim 12, wherein compressive stress measured through a method of ASTM C770-16 at a depth of about 50 μm from the surface of the strengthened glass substrate is about 80 MPa or greater with respect to the thickness direction.

20. A display device comprising:
a display module; and
a window disposed on the display module and including a compressive stress layer, wherein
the compressive stress layer includes:
a first region having a first compressive stress change rate;
a second region having a second compressive stress change rate different from the first compressive stress change rate; and
a third region having a third compressive stress change rate different from the first compressive stress change rate and the second compressive stress change rate,
each of the first compressive stress change rate, the second compressive stress change rate and the third compressive stress change rate is a compressive stress change rate according to depth with respect to a thickness direction,
a minimum depth from a surface of the window to a border between the first region and the second region is in a range of about 5 μm to about 15 μm with respect to the thickness direction,
a minimum depth from a surface of the window to a border between the second region and the third region is in a range of about 20 μm to about 40 μm with respect to the thickness direction, and
the compressive stress layer has a thickness in a range of about 100 μm to about 130 μm.
